(19) United States
(12) Patent Application Publication
(10) Pub. No.: US 2014/0011339 A1
(43) Pub. Date: Jan. 9, 2014

(54) METHOD FOR REMOVING NATIVE OXIDE AND RESIDUE FROM A GERMANIUM OR III-V GROUP CONTAINING SURFACE

(71) Applicant: Applied Materials, Inc., Santa Clara, CA (US)

(72) Inventors: Bo ZHENG, Saratoga, CA (US); Avgerinos V. GELATOS, Redwood City, CA (US); Ahmed KHALED, Anaheim, CA (US)

(73) Assignee: APPLIED MATERIALS, INC., Santa Clara, CA (US)

(21) Appl. No.: 13/929,496

(22) Filed: Jun. 27, 2013

Related U.S. Application Data
(60) Provisional application No. 61/668,642, filed on Jul. 6, 2012.

(51) Int. Cl. H01L 21/3065

(52) U.S. Cl. CPC H01L 21/3065
USPC 438/466; 438/715

(57) ABSTRACT

Native oxides and residue are removed from surfaces of a substrate by performing a hydrogen remote plasma process on the substrate. In one embodiment, the method for removing native oxides from a substrate includes transferring a substrate containing native oxide disposed on a material layer into a processing chamber, wherein the material layer includes a Ge containing layer or a III-V compound containing layer, supplying a gas mixture including a hydrogen containing gas from a remote plasma source into the processing chamber, and activating the native oxide by the hydrogen containing gas to remove the oxide layer from the substrate.

### CROSS-REFERENCE TO RELATED APPLICATIONS

This application claims benefit of U.S. Provisional Application Ser. No. 61/668,642 filed Jul. 6, 2012 (Attorney Docket No. APPM/17530L), which is incorporated by reference in their entirety.

### BACKGROUND OF THE INVENTION

1. Field of the Invention

Embodiments of the present invention relate generally to semiconductor substrate processing and, more particularly, to systems and methods for cleaning native oxide and residue from a substrate surface having germanium or III-V group containing materials.

2. Description of the Related Art

In the microfabrication of integrated circuits and other devices, electrical interconnect features, such as contacts, vias, and lines, are commonly constructed on a substrate using high aspect ratio apertures formed in a dielectric material. The presence of native oxides and other contaminants such as etch residue within these small apertures is highly undesirable, contributing to void formation during subsequent metalization of the aperture and increasing the electrical resistance of the interconnect feature.

A native oxide typically forms when a substrate surface is exposed to oxygen and/or water. Oxygen exposure occurs when substrates are moved between processing chambers at atmospheric or ambient conditions, or when a small amount of oxygen remains in a processing chamber. In addition, native oxides may result from contamination during etching processes, prior to or after a deposition process. Native oxide films are usually very thin, for example between 5-20 angstroms, but thick enough to cause difficulties in subsequent fabrication processes. Furthermore, native oxide may cause high contact resistance in source and drain areas and adversely increase the thickness of equivalent of oxide (EOT) in channel areas. Therefore, a native oxide layer is typically undesirable and needs to be removed prior to subsequent fabrication processes.

In conventional practice, NF₃ gas is often used to remove native oxide from a substrate surface which typically is a silicon surface. As circuit densities increase for next generation devices, the widths of interconnects, such as vias, trenches, contacts, gate structures and other features, as well as the dielectric materials therebetween, have decreased to 32 nm, 22 nm and 14 nm in width. Different materials are constantly developed to provide better electrical performance in semiconductor devices as the device dimension shrinks. For example, Ge containing materials, III-V group materials or III-V group compounds, such as Ge, SiGe, GaAs, InP, InAs, GaAs, GaP, InGaAs, and InGaAsP, and the like, are getting more and more attention for use in source-drain, channel, gate structure, metal silicide, or other regions of semiconductor devices. However, conventional native oxide removal technique by dry etching cannot efficiently remove native oxide from these surfaces, since conventional techniques are typically designed to remove native silicon oxide layer, in which the silicon atoms are attacked by NH₄F or NH₄F.NF forming solid by-produce (NH₄)₂SiF₆ and sublimated into vapor phase gas, which is readily pumped out of the processing chamber. In contrast, Ge containing, III-V group materials or III-V group compounds do not react with NH₄F or NH₄F.NF to form a vapor gas by product or readily sublimated into gas phase by-product which can be pumped out of the processing chamber. Instead, the conventional fluorine cleaning techniques may undesirably generate particles or solid by-product after reacting with the Ge containing, III-V group materials or III-V group compounds, thereby adversely creating surface contamination or keep the native oxide intact, which may eventually lead to device failure.

Other conventional cleaning techniques for removing native oxides from a surface exist but generally have one or more drawbacks. Sputter etch processes have been used to reduce or remove contaminants, but are generally only effective in large features or in small features having low aspect ratios, such as less than about 4:1. In addition, sputter etch processes can damage other material layers disposed on the substrate by physical bombardment. Wet etch processes utilizing hydrofluoric acid are also used to remove native oxides, but are less effective in smaller features with aspect ratios exceeding 4:1, as surface tension prevents acids from wetting the entire feature. In addition, conventional HF cannot remove natives of Ge and III-V group compounds.

Accordingly, there is a need in the art for methods of removing native oxides and residue from a substrate surface having germanium containing or III-V group containing materials.

### SUMMARY OF THE INVENTION

Embodiments of the present invention provide methods for removing native oxides and residue by performing a hydrogen containing remote plasma source process on the substrate. In one embodiment, the method for removing native oxides from a substrate includes transferring a substrate containing native oxide disposed on a material layer into a processing chamber, wherein the material layer includes a Ge containing layer or a III-V group containing layer, supplying a gas mixture including a hydrogen containing gas from a remote plasma source into the processing chamber, and activating the native oxide with the hydrogen containing gas to remove the oxide layer from the substrate.

In another embodiment, a method for removing native oxides from a substrate includes transferring a substrate containing native oxide disposed on a material layer into a processing chamber, wherein the material layer includes a Ge containing layer or a III-V group containing layer, supplying a gas mixture including a hydrogen containing gas from a remote plasma source into the processing chamber, maintaining a substrate temperature between about 100 degrees Celsius and about 400 degrees Celsius, and activating the native oxide with the hydrogen containing gas to remove the oxide layer from the substrate.

In yet another embodiment, a method for removing native oxides from a substrate includes transferring a substrate containing native oxide disposed on a material layer into a processing chamber, wherein the material layer includes a Ge containing layer or a III-V group containing layer, supplying a gas mixture including a H₂ from a remote plasma source into the processing chamber, maintaining a substrate temperature between about 100 degrees Celsius and about 400 degrees Celsius, and activating the native oxide with the hydrogen containing gas to remove the oxide layer from the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic cross-sectional view of a processing chamber configured to perform a cleaning process according to one or more embodiments of the invention.

FIG. 2 is a schematic plan view diagram of an exemplary multi-chamber processing system configured to perform a cleaning process on a substrate, according to one or more embodiments of the invention.

FIG. 3 is a flowchart of a method for processing a substrate in a processing chamber, according to one or more embodiments of the present invention.

FIG. 4A-4B are cross-sectional views of a substrate processed in the processing chamber according to the method depicted in FIG. 3, according to one or more embodiments of the present invention.

FIG. 5 is a cross-sectional view of a semiconductor device formed on a substrate that may utilize the method depicted in FIG. 3, according to one or more embodiments of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

As will be explained in greater detail below, a substrate having a surface is treated to remove native oxides or other contaminants prior to forming a device structure, such as a gate structure, a contact structure, a metal-insulator-semiconductor (MIS), a metal silicide layer, or the like, on the substrate. The term “substrate” as used herein refers to a layer of material that serves as a basis for subsequent processing operations and includes a surface to be cleaned. For example, the substrate can include one or more material containing germanium or III-V group containing compounds, such as Ge, SiGe, GaAs, InP, InAs, GaAs, GaP, InGaAs, InGaAsP, GaSb, InSb and the like, or combinations thereof. Furthermore, the substrate can also include dielectric materials such as silicon dioxide, organosilicates, and carbon doped silicon oxides. The substrate may also include one or more conductive metals, such as nickel, titanium, platinum, molybdenum, rhenium, osmium, chromium, iron, aluminum, copper, tungsten, or combinations thereof. Further, the substrate can include any other materials such as metal nitrides, metal oxides and metal alloys, depending on the application. In one or more embodiments, the substrate can form a contact structure, a metal silicide layer, or a gate structure including a gate dielectric layer and a gate electrode layer to facilitate connecting with an interconnect feature, such as a plug, via, contact, line, and wire, subsequently formed thereon, or suitable structures utilized in semiconductor devices.

Moreover, the substrate is not limited to any particular size or shape. The substrate can be a round wafer having a 200 mm diameter, a 300 mm diameter, a 450 mm diameter or other diameters. The substrate can also be any polygonal, square, rectangular, curved or otherwise non-circular workpiece, such as a polygonal glass, plastic substrate used in the fabrication of flat panel displays.

Embodiments of the present invention describe about a pre-cleaning process may be used to clean a substrate surface prior to a deposition or an etching process. The substrate surface may include a Ge containing or III-V group containing layer. The pre-cleaning process utilizes a hydrogen gas remote plasma source supplying in a processing chamber to react with the native oxide or other contaminants, thereby efficiently removing the undesired native oxide or other contaminants from the substrate surface.

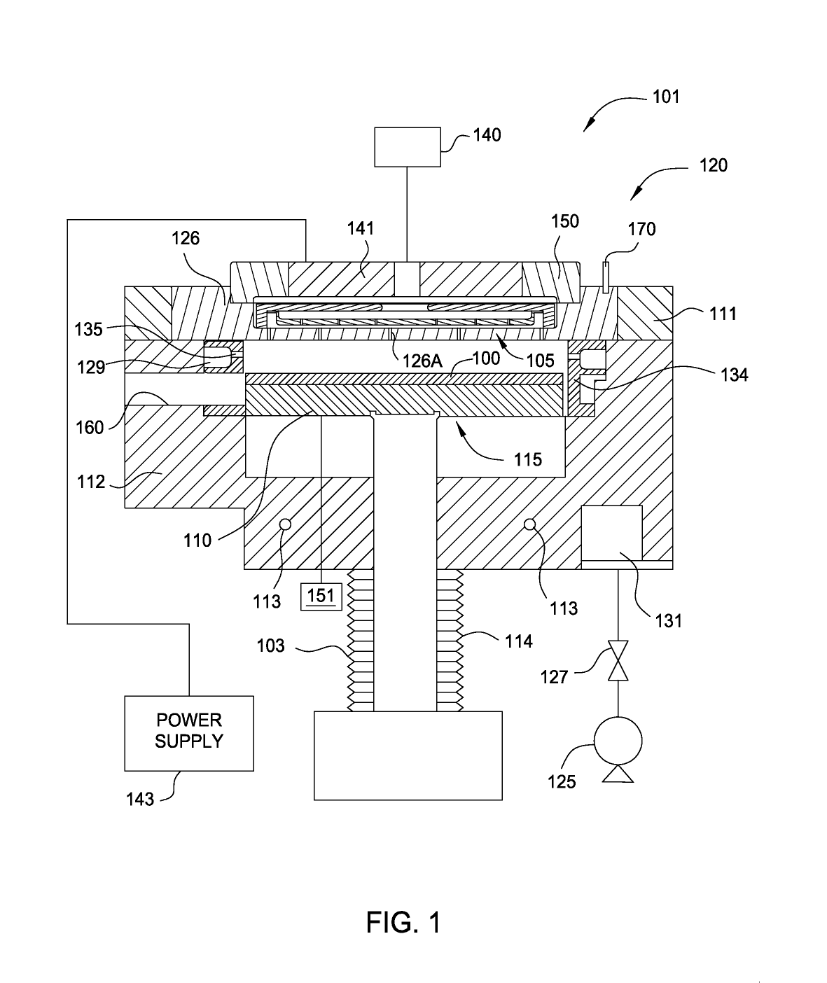

FIG. 1 is a schematic cross-sectional view of a processing chamber 101 configured to perform a two-step plasma cleaning process according to one or more embodiments of the invention. Processing chamber 101 includes a lid assembly 120 disposed at an upper end of a chamber body 112, and a support assembly 115 disposed within chamber body 112. Processing chamber 101 is also coupled to a remote plasma generator 140. Exemplary remote plasma generators are available from supplier such as MKS Instruments, Inc., and Advanced Energy Industries, Inc. Processing chamber 101 and the associated hardware are formed from one or more process-compatible materials, for example, aluminum, anodized aluminum, nickel plated aluminum, quartz, silicon coating, nickel plated aluminum 6061-T6, stainless steel, as well as combinations and alloys thereof. The processing chamber 101 is particularly useful for performing the plasma assisted dry etch process (i.e. the “preclean process”). The processing chamber 101 may be an APC (active pre-cleaning chamber), Preclean PCII, PCXT or Siconi chambers which are available from Applied Materials, Santa Clara, Calif. It is noted that other vacuum chambers available from other manufactures may also be utilized to practice the present invention. In some embodiments, water vapor may be applied to the processing chamber to minimize consumption of coating formed in the plasma cavity.

A support assembly 115 is disposed within chamber body 112. The support assembly 115 is raised and lowered by a shaft 114, which is enclosed by a bellows 103. The support assembly 115 includes a substrate support member 110, which supports a substrate 100 thereon during process. A RF power 151 may be coupled to the support assembly 115 to provide a RF bias power to a substrate 100 disposed thereon during processing.

Chamber body 112 includes a slit valve opening 160 formed in a sidewall thereof to provide access to the interior of processing chamber 101. The substrate 100 may be transported in and out of processing chamber 101 through the slit valve opening 160 to an adjacent transfer chamber and/or load-lock chamber (not shown), or another chamber within a cluster tool. Exemplary cluster tools include, but are not limited to, the PRODUCER®, CENTURA®, ENDURA®, and ENDURA® SL platforms, available from Applied Materials, Inc., located in Santa Clara, Calif.

Chamber body 112 also includes channels 113 formed therein for flowing a heat transfer fluid therethrough. The heat transfer fluid may be a heating fluid or a coolant and is used to control the temperature of chamber body 112 during processing and substrate transfer. The temperature of chamber body 112 is regulated to prevent unwanted condensation of process gas or byproducts on the chamber walls. Exemplary heat transfer fluids include water, ethylene glycol, or a mixture thereof.

Chamber body 112 further includes a liner 134 that surrounds support assembly 115 and is removable for servicing and cleaning. Liner 134 may be made of a metal such as aluminum, a ceramic material, or other material compatible for use during the process of substrates in processing chamber 101. Liner 134 include one or more apertures 135 and a pumping channel 129 formed therein that is in fluid communication with a vacuum pump 125 through a vacuum port 131 formed through the chamber body 112. Apertures 135 provide a flow path for gases into pumping channel 129, and the pumping channel 129 provides a flow path through liner 134 so the gases can exit the processing chamber 101 via the vacuum pump 125. A throttle valve 127 to regulate flow of gases leaving the processing chamber 101 via the vacuum pump 125.

Lid assembly 120 contains a number of components stacked together. For example, lid assembly 120 contains a lid rim 111, gas delivery assembly 105, and top plate 150. Lid rim 111 is designed support the components making up lid assembly 120 and is coupled to an upper surface of chamber body 112. Gas delivery assembly 105 is coupled to the lid rim 111 and is arranged to make minimum thermal contact therewith. The components of lid assembly 120 may be constructed of a material having a high thermal conductivity and low thermal resistance, such as an aluminum alloy with a highly finished surface, for example.

Gas delivery assembly 105 may comprise a gas distribution plate 126 or showerhead. In one embodiment, the gas distribution plate 126 may be fabricated by quartz so as to reduce likelihood of hydrogen radical recombination rate. A gas supply panel (not shown) is used to provide the one or more gases to processing chamber 101 through the gas distribution plate 126. The particular gas or gases that are used depend upon the processes to be performed within processing chamber 101. To facilitate the plasma cleaning processes as described herein, such process gases include ammonia, nitrogen trifluoride, and one or more carrier and purge gases, and other suitable gases.

In some embodiments, instead of using remote plasma generator 140, lid assembly 120 may include an electrode 141 to generate a plasma of reactive species within lid assembly 120. In such an embodiment, electrode 141 is supported on top plate 150 and is electrically isolated therefrom, for example with an isolator ring (not shown). Also in such an embodiment, electrode 141 is coupled to a power supply 143 and gas delivery assembly 105 is connected to ground. Accordingly, a plasma of the one or more process gases can be struck in a volume 137 formed between electrode 141 and gas delivery assembly 105. Thus, the plasma is well confined or contained within lid assembly 120.

Any power source may be used in processing chamber 101 that is capable of activating the gases into reactive species and maintaining the plasma of reactive species, whether remote plasma generator 140 or electrode 141 is used to generate a desired plasma. For example, radio frequency (RF), direct current (DC), inductively coupled, alternating current (AC), or microwave (MW) based power discharge techniques may be used. Plasma activation may also be generated by a thermally based technique, a gas breakdown technique, a high intensity light source (e.g., UV energy), or exposure to an x-ray source.

Gas delivery assembly 105 may be heated depending on the process gases and operations to be performed within processing chamber 101. In one embodiment, a heating element 170, such as a resistive heater, is coupled to gas delivery assembly 105 regulating the temperature of gas delivery assembly 105. In the embodiment illustrated in FIG. 1, the bottom surface of gas delivery assembly 105 is substantially parallel to the top surface of substrate support member 110. In other embodiments, the bottom surface of gas delivery assembly 105 may be dome-shaped or otherwise configured in order to optimize gas flow and heating of a substrate in processing chamber 101. In one embodiment, the gas delivery assembly 105 may be heated to a temperature between about 50 degrees Celsius and about 80 degrees Celsius.

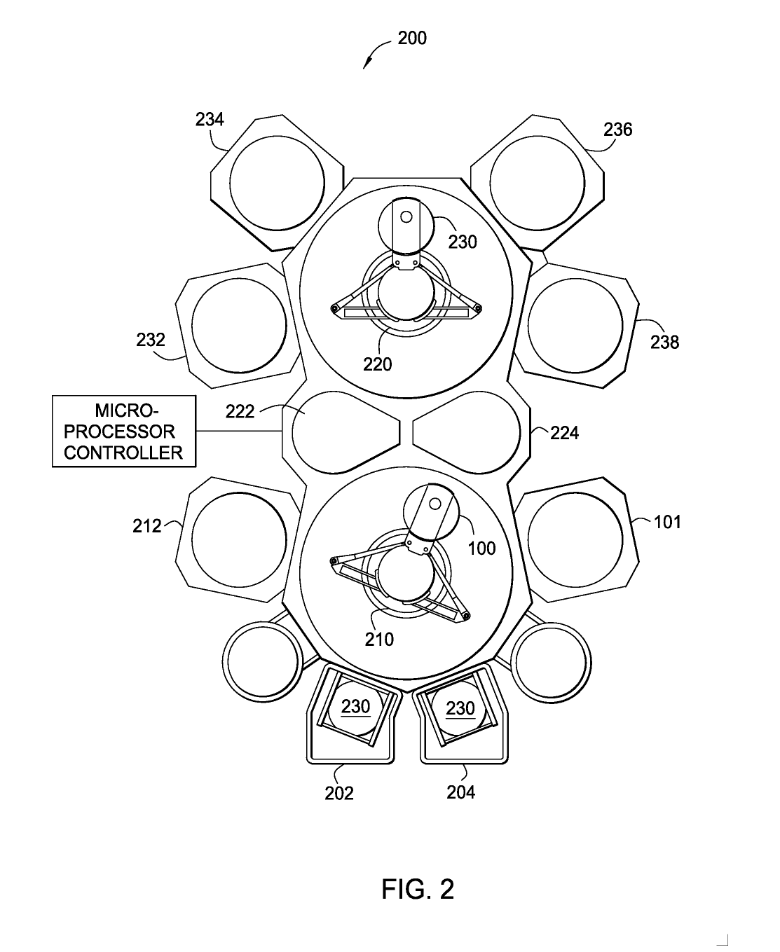

FIG. 2 is a schematic plan view diagram of an exemplary multi-chamber processing system 200 configured to perform a pre-cleaning process on substrates 100, according to one or more embodiments of the invention. Multi-chamber processing system 200 includes one or more load lock chambers 202, 204 for transferring substrates 100 into and out of the vacuum portion of multi-chamber processing system 200. Consequently, load lock chambers 202, 204 can be pumped down to introduce substrates into multi-chamber processing system 200 for processing under vacuum. A first robot 210 transfers substrates 100 between load lock chambers 202 and 204, transfer chambers 222 and 224, and a first set of one or more processing chambers 212 and 101. A second robot 220 transfers substrates 100, 230 between transfer chambers 222 and 224 and processing chambers 232, 234, 236, 238.

One or both of processing chambers 101 and 212 may be configured to perform a pre-cleaning process, according to embodiments of the invention described herein. The transfer chambers 222, 224 can be used to maintain ultra-high vacuum conditions while substrates are transferred within multi-chamber processing system 200. Processing chambers 232, 234, 236, 238 are configured to perform various substrate-processing operations including cyclical layer deposition (CLD), atomic layer deposition (ALD), chemical vapor deposition (CVD), physical vapor deposition (PVD), and the like. In one embodiment, one or more of processing chambers 232, 234, 236, 238 are configured to deposit a contact structure, a gate structure, or a pre-gate surface, or other suitable structures, comprising a plurality of material layers.

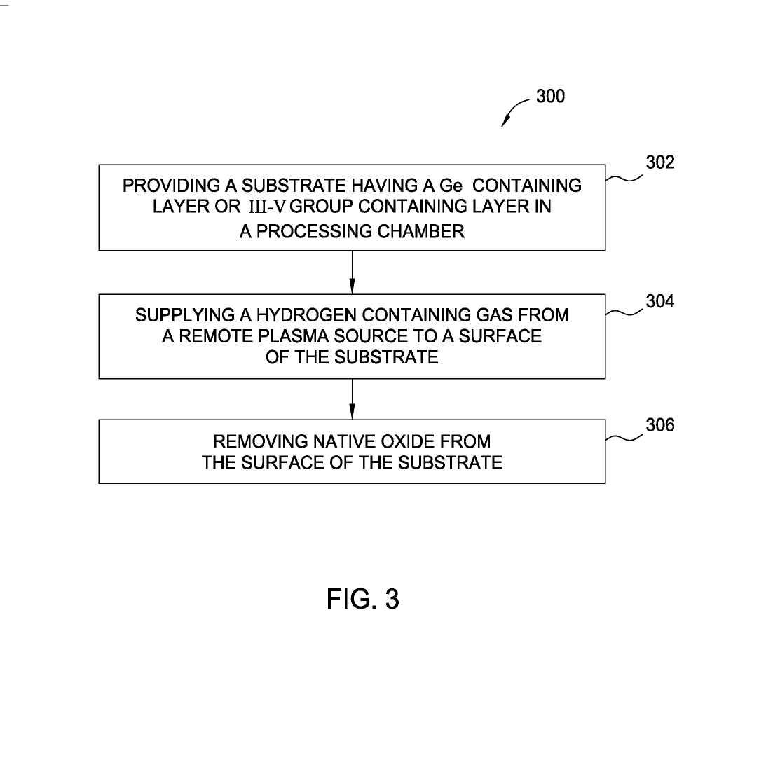

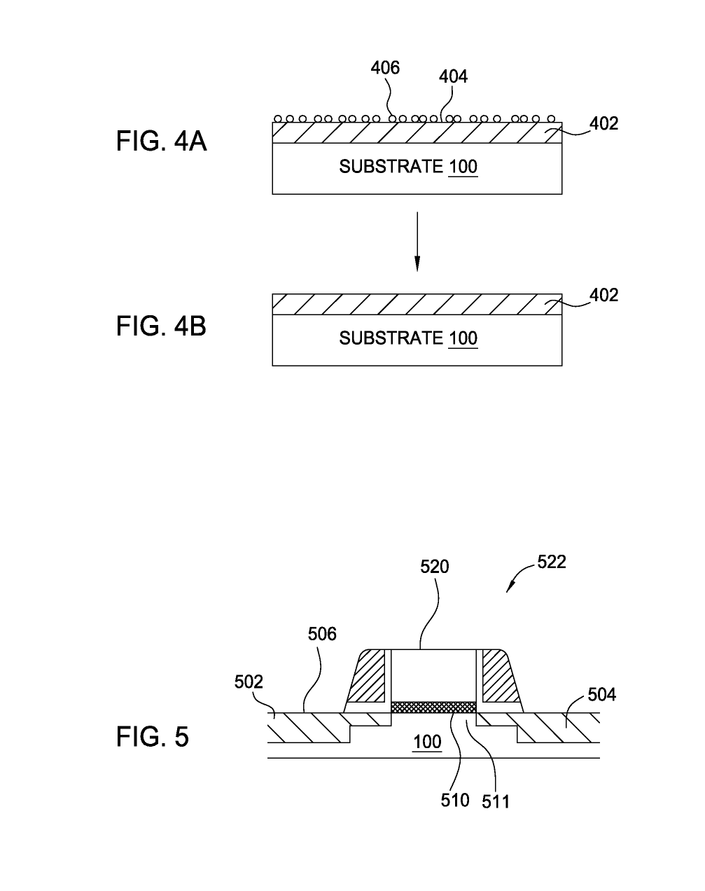

FIG. 3 is a flow diagram of a process 300 for removing native oxide from a substrate surface having a germanium containing or III-V compound containing material. FIGS. 4A-4B are cross-sectional views of the substrate when performing the native oxide removal process at the different manufacturing stages depicted in FIG. 3.

The process 300 starts at step 302 by transferring the substrate 100, as shown in FIG. 4A, into a processing chamber, such as the processing chamber 101 depicted in FIG. 1, to perform a native oxide removal process. In one embodiment, the substrate 100 may be a 200 mm, 300 mm or 450 mm silicon wafer, or other substrate used to fabricate microelectronic devices and the like. In one embodiment, the substrate 100 may be a material such as crystalline silicon (e.g., Si<100>, Si<111> or Si<001>), silicon oxide, strained silicon, silicon₍₁₋ₓ₎germaniumₓ, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 100 may have a circular wafer, as well as, rectangular or square panels. Unless otherwise noted, the examples described herein are conducted on substrates having a 300 mm diameter or a 450 mm diameter. In one embodiment, the substrate 100 has a material layer 402 disposed thereon. The material layer 402 may be a germanium (Ge) containing layer, such as Ge or SiGe, a III-V compound containing layer, and the like. Suitable examples of the III-V compound containing layer include GaAs, InP, InAs, GaAs, GaP, InGaAs, InGaAsP, GaSb, InSb, the like, or combinations thereof. Native oxide 406 is formed on a surface 404 of the material layer 402 on the substrate 100, due to the exposure to either atmosphere or to one or more fabrication processes that cause native oxide 406 to form, such as a wet process.

As discussed above, as the substrate 100 may be exposed to air or ambient atmosphere, native oxide 406 formed on the substrate surface 404 may have oxygen, nitrogen, carbon, sulfur, or other elements commonly contained in the air. Accordingly, the native oxide removal process as performed here is configured to remove the native oxide 406 including not only the oxide layer but also other derivations layers, including carbon, nitrogen, sulfur elements or the like that may be found on the substrate surface 404.

At step 304, a pre-cleaning gas mixture is supplied into the processing chamber 101 to pre-clean the substrate surface 404 for removing the native oxide 406 from the substrate surface 404 prior to performing a deposition or etching process. Removal of native oxides 406 or other source of contaminants from the substrate 100 may provide a low contact resistance surface that forms a good contact surface with the subsequently deposited layer. Furthermore, removal of native oxides 406 may also improve adhesion at the interface when the subsequent layer is formed thereon.

A plasma formed from the pre-cleaning gas mixture is used to plasma treat the surfaces 404 of the substrate 100 to activate the native oxide 406 or other source of contaminants into an excited state, such as in radical forms, which may then easily react with pre-cleaning gas mixture, forming volatile gas byproducts which is readily pumped out of the processing chamber 101.

In one embodiment, the pre-cleaning gas mixture includes at least a hydrogen containing gas and optionally an inert gas. It is believed that the inert gas supplied in the pre-cleaning gas mixture may assist increasing the life time of the ions in the plasma formed from the pre-cleaning gas mixture and/or provide gentle bombardment of the substrate surface. Increased life time of the ions may assist with reacting and activating the native oxide 406 on the substrate 100 more thoroughly, thereby enhancing the removal of the activated native oxide 406 from the substrate 100 during the pre-cleaning process.

In addition, the hydrogen containing gas supplied in the pre-cleaning gas mixture may react with the oxygen atoms of the native oxide 406, activating the native oxide 406 formed on the substrate surface to a state easily to be evaporated, thereby assisting the removal of the native oxide 406 from the substrate surface 404. In one embodiment, the hydrogen containing gas supplied into the processing chamber 101 includes at least one of H₂ and the like. Alternatively, a nitrogen containing gas, such as N₂, N₂O, NO₂, NH₃, N₂H₄, may also be used to be supplied in the pre-cleaning gas. The inert gas supplied into the processing chamber 101 includes at least one of Ar, He, Kr, Ne, and the like. In an exemplary embodiment, the hydrogen containing gas supplied in the processing chamber 101 to perform the pretreatment process is H₂ gas and the inert gas is Ne.

In one embodiment, the hydrogen containing gas may be supplied from a remote plasma source, such as the remote plasma generator 140 depicted in FIG. 1, into the processing chamber 101. It is believed that remotely dissociated hydrogen gas and/or other gases can provide high density and low energy atomic hydrogen or other types of active species, as compared to conventional in-chamber plasma which may provide high energy but relatively low density hydrogen radicals, thereby efficiently reacting with the native oxide 406 on the substrate surface 404, thereby providing a more efficient surface activating process and therefore increasing the efficiency of the pre-cleaning/pre-treating substrate surface during pre-cleaning process with minimum damage to substrates. It is believed that atomic hydrogen has higher degree of reactivity, which may react with dissociated oxygen species more efficiently and thoroughly.

During the remote hydrogen pre-cleaning process, several process parameters may be regulated to control the pre-cleaning process. In one exemplary embodiment, a process pressure in the processing chamber 101 is regulated between about 10 mTorr to about 500 mTorr, for example, at about 100 mTorr. A RF bias power to a substrate support may be applied to maintain a plasma in the pre-cleaning gas mixture. For example, a RF bias power of about 50 Watts to about 150 Watts may be applied to maintain a plasma inside the processing chamber 101. A remote RF source power of between about 1000 Watts and about 10000 Watts is supplied to the remote process chamber to facilitate dissociating gases and later supplying into the processing chamber. The frequency at which the power is applied around 400 kHz. The frequency can range from about 50 kHz to about 2.45 GHz. The hydrogen containing gas supplied in the pre-cleaning gas mixture may be flowed into the chamber at a rate between about 100 sccm to about 2000 sccm, such as about 400 sccm, and/or the optional inert gas supplied in the pretreatment gas mixture may be flowed at a rate between about 100 sccm and about 1000 sccm. A substrate temperature is maintained between about 100 degrees Celsius to about 400 degrees Celsius, such as about 250 degrees Celsius.

It is noted that the amount of each gas introduced into the processing chamber may be varied and adjusted to accommodate, for example, the thickness of the native oxide layer to be removed, the geometry of the substrate being cleaned, the volume capacity of the plasma, the volume capacity of the chamber body, as well as the capabilities of the vacuum system coupled to the chamber body.

In one or more embodiments, the gases added to provide a pre-cleaning gas mixture having at least a 5:1 molar ratio of hydrogen containing gas to inert gas. In one or more embodiments, the molar ratio of the hydrogen containing gas to inert gas is at least about 1:1. In one example, the molar ratio of the hydrogen containing gas to inert gas is between about 1:1 and about 5:1.

At step 306, after supplying the pre-cleaning gas mixture in the processing chamber 101 to react with the native oxide 406 on the substrate surface 404, the native oxide 406 can then be removed from the substrate surface 404, as shown in FIG. 4B, exposing the material layer 402 for further processing.

In one embodiment, the substrate is subjected to perform the pre-cleaning process for between about 10 seconds to about 180 seconds, depending on the operating temperature, pressure and flow rate of the gas. For example, the substrate can be exposed for about 30 seconds to about 120 seconds. In an exemplary embodiment, the substrate is exposed for about 60 seconds or less.

After the native oxide removal process is performed, the underlying surface of the material layer 402 is exposed. As discussed above, the material layer 402 may be a channel region 511 formed in a gate structure 522, as depicted in FIG. 5. Alternatively, the material layer 402 may be a source 502 or a drain region 504 formed in the substrate 100 before metal deposition for silicide, germanide or metal III-V alloy or MIS. Furthermore, the material layer 402 may be any suitable layer or interface, such as the interface 510 (at the interface between the substrate and prior to forming the gate structure 522), interface 520, 506 (on the gate structure ready to form a contact structure, e.g., pre-contact interface or pre-silicidation surface). It is noted that the material layer 402 may be used in any suitable interface or surface that may be manufactured from a Ge containing layer or III-V compound containing layer as needed.

After the native oxide 406 is removed, the substrate 100 may be then transferred to a degas chamber, such as one of the processing chambers 212, 238, 236, 234, 232 incorporated in the system 200 to perform a degas process so as to remove moisture from the substrate surface. After the degassing process, a depositing process, such as a physical vapor deposition (PVD), chemical vapor deposition (CVD), atomic layer deposition (ALD), and the like, or an etching process may be performed on the substrate 100 to continue the manufacture of the semiconductor device.

In summation, one or more embodiments of the present invention provide methods for removing native oxides and residue by performing a hydrogen containing plasma pre-cleaning process on a substrate having a Ge containing layer or a III-V compound containing material. Advantages of such embodiments include the formation of clean, native oxide-free surfaces, even when such surfaces are disposed on high aspect ratio features and small dimensions.

While the foregoing is directed to embodiments of the present invention, other and further embodiments of the invention may be devised without departing from the basic scope thereof, and the scope thereof is determined by the claims that follow.

We claim:

1. A method for removing native oxides from a substrate, comprising:
transferring a substrate containing native oxide disposed on a material layer into a processing chamber, wherein the material layer is a Ge containing layer or a III-V group containing layer;
supplying a gas mixture including a hydrogen containing gas from a remote plasma source into the processing chamber; and
activating the native oxide with the hydrogen containing gas to remove the oxide layer from the substrate.

2. The method of claim 1, wherein supplying the hydrogen containing gas into the processing chamber further comprises:
maintaining the substrate at a temperature of between about 100 degrees Celsius and about 400 degrees Celsius.

3. The method of claim 1, wherein the gas mixture further includes an inert gas.

4. The method of claim 1, wherein the material layer is a material selected from a group consisting of Ge, SiGe, GaAs, InP, InAs, GaAs, GaP, InGaAs, InGaAsP, GaSn and InSb.

5. The method of claim 1, wherein the material layer is utilized to form source and drain regions formed in the substrate.

6. The method of claim 1, wherein the material layer is formed as part of a gate structure or a surface configured to form a contact structure.

7. The method of claim 1, wherein the hydrogen containing gas used in the gas mixture include at least one of H₂, NH₃ and H₂N₄.

8. The method of claim 3, wherein the inert gas used in the gas mixture includes at least one of Ar, He, Ne and Kr.

9. The method of claim 3, wherein a molar ratio of hydrogen containing gas to inert gas is controlled at between about 1:1 and about 5:1.

10. The method of claim 1 further comprising:
applying a bias power to the substrate while removing the oxide layer from the substrate.

11. The method of claim 1 further comprising:
maintaining a process pressure at between about 10 mTorr and about 500 mTorr while removing the oxide layer from the substrate.

12. A method for removing native oxides from a substrate, comprising:
transferring a substrate containing native oxide disposed on a material layer into a processing chamber, wherein the material layer is a Ge containing layer or a III-V group containing layer;
supplying a gas mixture including a hydrogen containing gas from a remote plasma source into the processing chamber;
maintaining a substrate temperature between about 100 degrees Celsius and about 400 degrees Celsius; and
activating the native oxide with the hydrogen containing gas to remove the oxide layer from the substrate.

13. The method of claim 12, wherein the material layer is formed from a material selected from a group consisting of Ge, SiGe, GaAs, InP, InAs, GaAs, GaP, InGaAs, InGaAsP, GaSn and InSb.

14. The method of claim 12, wherein the hydrogen containing gas is H₂ or NH₃ or H₂N₄.

15. The method of claim 12, wherein the pre-cleaning gas mixture further includes an inert gas.

16. The method of claim 12, wherein a molar ratio of hydrogen containing gas to inert gas is controlled at between about 1:1 and about 5:1.

17. The method of claim 12, wherein supplying the hydrogen containing gas into the processing chamber further comprises:
applying a bias power to the substrate during processing.

18. A method for removing native oxides from a substrate, comprising:
transferring a substrate containing native oxide disposed on a material layer into a processing chamber, wherein the material layer includes a Ge containing layer or a III-V group containing layer;
supplying a gas mixture including hydrogen containing gas from a remote plasma source into the processing chamber;
maintaining a substrate temperature between about 100 degrees Celsius and about 400 degrees Celsius; and
activating the native oxide with the hydrogen containing gas to remove the oxide layer from the substrate.

19. The method of claim 18, wherein the material layer is utilized to form source and drain regions formed in the substrate.

20. The method of claim 18, wherein the material layer is formed as part of a gate structure or a surface configured to form a contact structure.
